(19) United States
(12) Patent Application Publication
(10) Pub. No.: US 2025/0073983 A1
(43) Pub. Date: Mar. 6, 2025

(54) TEMPLATE, MANUFACTURING METHOD FOR TEMPLATE, AND MANUFACTURING METHOD FOR SUBSTRATE WITH PATTERN USING TEMPLATE

(71) Applicant: Kioxia Corporation, Tokyo (JP)

(72) Inventor: Daisuke KOMATSU, Yokkaichi Mie (JP)

(73) Assignee: Kioxia Corporation, Tokyo (JP)

(21) Appl. No.: 18/461,681

(22) Filed: Sep. 6, 2023

(30) Foreign Application Priority Data
Sep. 7, 2022 (JP) 2022-142330

(51) Int. Cl. B29C 59/02

(52) U.S. Cl. CPC B29C 59/026; G03F 7/11

(57) ABSTRACT

A template 30 includes a base material 300 in which a protruding portion 310 corresponding to a pattern is formed in a transfer region PA to be pressed against a material to be transferred 60, a underlayer film 330 that covers, of the transfer region PA, only a distal end surface 311 of the protruding portion 310, and a monomolecular film 340 that covers the underlayer film 330.

### CROSS-REFERENCE TO RELATED APPLICATION

This application is based upon and claims the benefit of priority from Japanese Patent Application No. 2022-142330, filed on Sep. 7, 2022, the entire contents of which are incorporated herein by reference.

### BACKGROUND OF THE INVENTION

### Field of the Invention

An embodiment of the present invention relates to a template, a manufacturing method for the template, and a manufacturing method for a substrate with a pattern using the template.

### Description of the Related Art

As a method for forming a pattern, a method called imprinting is proposed. In imprinting, after a template with a formed three-dimensional pattern is put in a state of being pressed against a material to be transferred on a substrate, the material to be transferred is cured. This allows formation of a film with a transferred three-dimensional pattern on the substrate.

### BRIEF DESCRIPTION OF THE DRAWINGS

FIG. 1 is a diagram schematically showing a configuration of an imprinting apparatus including a template according to the present embodiment;

FIG. 2A is a view for explaining a step in imprinting;

FIG. 2B is a view for explaining a step in the imprinting;

FIG. 2C is a view for explaining a step in the imprinting;

FIG. 2D is a view for explaining a step in the imprinting;

FIG. 2E is a view for explaining a step in the imprinting;

FIG. 3A is a view for explaining a problem that may occur at the time of mold release or the like;

FIG. 3B is a view for explaining a problem that may occur at the time of mold release or the like;

FIG. 4 is a view showing a specific configuration of the template according to the present embodiment;

FIG. 5 is a view for explaining a manufacturing method for the template according to the present embodiment;

FIG. 6 is a view for explaining the manufacturing method for the template according to the present embodiment;

FIG. 7 is a view for explaining the manufacturing method for the template according to the present embodiment;

FIG. 8 is a view for explaining the manufacturing method for the template according to the present embodiment;

FIG. 9 is a view for explaining the manufacturing method for the template according to the present embodiment;

FIG. 10 is a view for explaining the manufacturing method for the template according to the present embodiment;

FIG. 11 is a view for explaining the manufacturing method for the template according to the present embodiment; and

FIG. 12 is a view showing a specific configuration of a template according to a modification.

FIG. 13 is a table showing the relationship between the materials of the monomolecular film and the materials of the underlayer film 330.

### DETAILED DESCRIPTION OF THE PREFERRED EMBODIMENT

The present embodiment will be described below with reference to the accompanying drawings. For easy understanding of the explanation, the same constitutional elements are denoted by the same reference characters as much as possible in the drawings, and a redundant explanation will be omitted.

A template 30 according to the present embodiment is mounted on an imprinting apparatus 10 and is used as an imprinting master. A configuration of the imprinting apparatus 10 will be described first prior to the explanation of the template 30.

The imprinting apparatus 10 is an apparatus that is used to manufacture a semiconductor device and is an apparatus that transfers a three-dimensional pattern onto a material to be transferred applied onto a substrate 20. A semiconductor device to be manufactured is, for example, a NAND-type flash memory. Note that a configuration of the template 30 (to be described later) can also be used to manufacture things other than semiconductor devices.

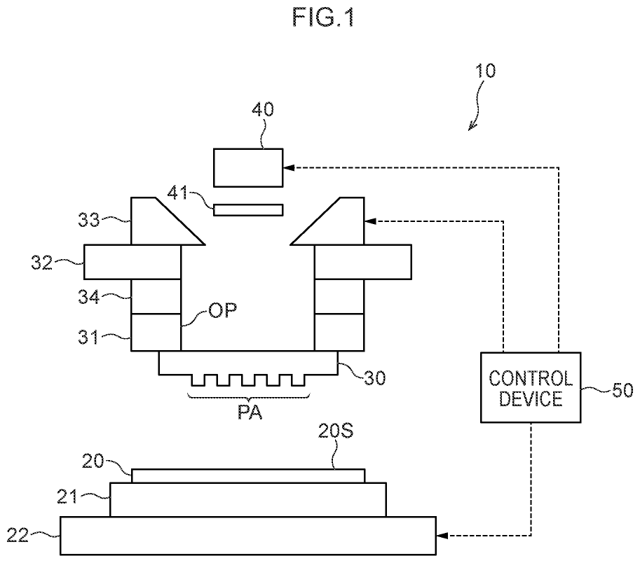

As shown in FIG. 1, the imprinting apparatus 10 includes a substrate chuck 21, a substrate stage 22, the template 30, a master chuck 31, a base 32, an alignment sensor 33, a light source 40, and a control device 50.

The substrate chuck 21 is a device that holds the substrate 20 and is, for example, a vacuum chuck. The substrate 20 as a pattern transfer target is held from a lower side by the substrate chuck 21 while a surface 20S thereof faces upward. The surface 20S of the substrate 20 has a film to be processed that is formed on the substrate 20. On the film to be processed, a liquid material to be transferred is applied in advance by an application apparatus (not shown). The substrate 20 according to the present embodiment is, for example, a semiconductor substrate, such as a silicon wafer. The above-described material to be transferred that is applied to the substrate 20 is cured with light from the light source 40 (to be described later) and functions as, for example, a resist at the time of etching of the film to be processed in a step after imprinting.

A closed container (not shown) called a FOUP is attached to the imprinting apparatus 10. A plurality of substrates 20 subjected in advance to processing, such as film formation or the like, in a previous step are housed in the FOUP. The substrate 20 that is being held by the substrate chuck 21 in FIG. 1 has been transported by a transport mechanism (not shown) after being taken out from the FOUP.

The substrate stage 22 is a device that supports the substrate chuck 21. The substrate stage 22 is capable of moving the substrate chuck 21 and the substrate 20 held by the substrate chuck 21 along an X direction and a Y direction that are parallel to the surface 20S and perpendicular to each other. The substrate stage 22 may be configured as an XYθ stage that is capable of further rotating the substrate 20 and the like in an XY plane. Operation of the substrate stage 22 is controlled by the control device 50 (to be described later).

The template 30 is a master with a three-dimensional pattern formed on a surface thereof. The three-dimensional pattern corresponds to a three-dimensional pattern to be transferred onto the material to be transferred above the substrate 20. The three-dimensional pattern is formed only in a partial region denoted by reference character PA of the surface (a surface on the lower side in FIG. 1) of the template 30. The region is a region that is to be pressed against the material to be transferred above the substrate 20. The region is hereinafter also called the “transfer region PA.” In the template 30, a whole including the three-dimensional pattern in the transfer region PA is made of a material transparent to a wavelength of light that is applied from the light source 40. A specific configuration of the template 30 will be described later.

The master chuck 31 is a device that holds the template 30 and is, for example, a mechanical clamp device. The template 30 is held by the master chuck 31 while the surface with the transfer region PA faces the lower side, i.e., a side with the substrate 20. An opening OP for allowing light from the light source 40 to pass through is formed in portions immediately above the transfer region PA of the master chuck 31 and the base 32.

A master driving portion 34 is a mechanism that is capable of causing the master chuck 31 to change in position in a direction perpendicular to the substrate 20. The master driving portion 34 is attached to the base 32 located on an upside of the master driving portion 34.

The alignment sensor 33 is a sensor for sensing a relative positional relationship between the template 30 and the substrate 20. To allow the sensing, respective alignment marks (not shown) are provided in advance on the template 30 and the substrate 20. The alignment sensor 33 images the alignment marks through the opening OP from an upper side and measures the degree of deviation between the alignment marks. The degree of deviation refers to, for example, a distance between the alignment mark provided on the template 30 and the alignment mark provided on the substrate 20. Formation of a three-dimensional pattern on the material to be transferred above the substrate 20 is performed in a state where the relative positional relationship between the template 30 and the substrate 20 is adjusted in advance such that the distance comes as close to 0 as possible.

The light source 40 is a device that applies light (e.g., ultraviolet light) for curing the material to be transferred. The light source 40 is, for example, a mercury lamp. The light source 40 can change intensity of emitted light. The light source 40 may be configured to be capable of changing a wavelength of emitted light. The light source 40 is also capable of curing the material to be transferred to a degree that enhances viscosity of the material to be transferred without completely curing the material to be transferred. Intensity and the like of light emitted from the light source 40 are adjusted by the control device 50.

An irradiation amount adjustment mechanism 41 may be arranged between the light source 40 and the substrate 20, i.e., at a position midway through a route of light to the substrate 20. The irradiation amount adjustment mechanism 41 adjusts an irradiation amount of light to arrive at the substrate 20 by mechanical operation. The irradiation amount adjustment mechanism 41 is, for example, a shutter device or a mirror device. If the irradiation amount adjustment mechanism 41 is arranged, the control device 50 adjusts an irradiation amount of light to arrive from the light source 40 at the substrate 20 by controlling operation of the irradiation amount adjustment mechanism 41.

The control device 50 is a device that performs integrated control on overall operation of the imprinting apparatus 10. The control device 50 is configured as a computer system having a CPU, a RAM, a ROM, and the like. Note that although the control device 50 may be built in the imprinting apparatus 10, the control device 50 may be mounted at a position away from the imprinting apparatus 10.

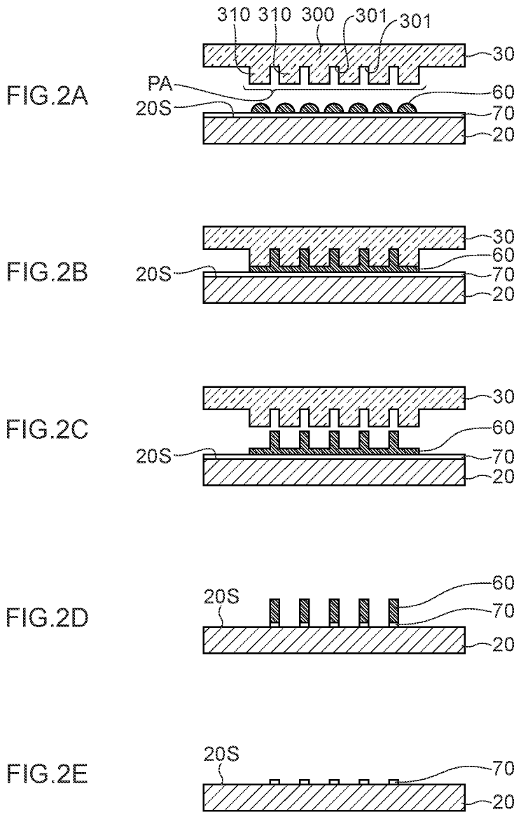

A flow of pattern transfer using the imprinting apparatus 10 will be described with reference to FIGS. 2A to 2E. States of the substrate 20 and the like in steps in imprinting are schematically shown in FIGS. 2A to 2E. In FIGS. 2A to 2E, an element denoted by reference numeral 60 is the material to be transferred. An element denoted by reference numeral 70 is the film to be processed, which is formed on the substrate 20. The elements will also be called the “material to be transferred 60” and the “film 70 to be processed” below.

First, as shown in FIG. 2A, the material to be transferred 60 is arranged above a surface of the substrate 20 (specifically on a surface of the film 70 to be processed). The arrangement of the material to be transferred 60 may be performed by, for example, dripping the material to be transferred 60 at a plurality of spots on the film 70 to be processed or forming a film of the material to be transferred 60 across a whole of the film 70 to be processed by spin coating or the like.

After that, as shown in FIG. 2B, a process of putting a portion (i.e., the transfer region PA) with the three-dimensional pattern of the template 30 into a state of being pressed against the material to be transferred 60 above the substrate 20 by lowering the master chuck 31 (not shown) is performed.

In the transfer region PA, a plurality of protruding portions 310 that protrude toward the substrate 20 and a plurality of recessed portions 301, each of which is a portion between the protruding portions 310, are present. The protruding portions 310 and the recessed portions 301 constitute the three-dimensional pattern. The three-dimensional pattern corresponds to a pattern to be formed on the material to be transferred 60. In the state in FIG. 2B, a gap between the template 30 and the substrate 20 is filled with the material to be transferred 60. Specifically, a space inside the recessed portion 301, a gap between a distal end of the protruding portion 310 and the film 70 to be processed, and the like are uniformly filled with the material to be transferred 60. As a result, the material to be transferred 60 that is a fluid at the time is in a shape corresponding to the three-dimensional pattern.

In a state shown in FIG. 2B, light is emitted from the light source 40. The light passes through the opening OP and passes through the template 30 and then arrives at the material to be transferred 60. For this reason, the material to be transferred 60 cures while maintaining the shape corresponding to the three-dimensional pattern.

When the curing of the material to be transferred 60 is completed, a process of removing the template 30 from the material to be transferred 60 is performed. Specifically, the master chuck 31 (not shown) is pulled up toward the upper side, as shown in FIG. 2C. With this pull-up, the substrate 20 and the template 30 are separated from each other, and the material to be transferred 60 is released from the three-dimensional pattern of the template 30. The surface of the film 70 to be processed is in a state of being covered with the material to be transferred 60 with a formed pattern.

Note that the formation of the pattern on the material to be transferred 60 is sequentially performed for a plurality of regions after the surface 20S is divided into the regions. This allows pattern formation over a wide range.

The substrate 20 having the material to be transferred 60 with the formed pattern (i.e., a substrate with a pattern) is, for example, moved to a different etching apparatus or the like in a later step, and an etching step for the film 70 to be processed using the material to be transferred 60 as a mask is performed. With this etching step, the film 70 to be processed is processed to form a three-dimensional pattern. For example, a semiconductor device having a wiring pattern in which metal is embedded in each recessed portion of the three-dimensional pattern is manufactured. A state immediately after the etching step for the film 70 to be processed using the material to be transferred 60 as the mask is schematically shown in FIG. 2D. A state after the material to be transferred 60 in the state in FIG. 2D is removed by ashing is schematically shown in FIG. 2E. As described above, a predetermined pattern corresponding to the three-dimensional pattern of the template 30 is formed on the film 70 to be processed.

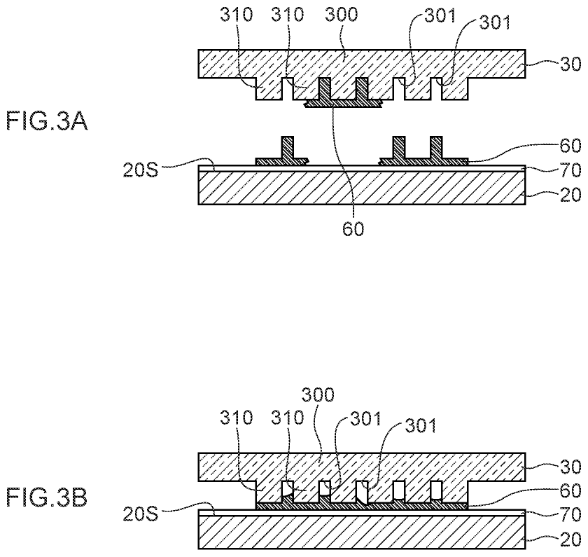

Mold releasability of the template 30 is a problem at the time of removing the template 30 from the material to be transferred 60 as described above. It is known that, if quartz is used as a material for the template 30, mold releasability for the material to be transferred 60 is low. If the mold releasability for the material to be transferred 60 is low, a situation where a part of the material to be transferred 60 is pulled up adhering to the template 30 at the time of mold release and is separated from the remainder may arise, as shown in, for example, FIG. 3A.

It is conceivable to, for example, cover a whole surface of the transfer region PA of the template 30 with a layer of a material low in wettability with the material to be transferred 60 as measures to prevent chipping of the material to be transferred 60.

However, in the above-described case, when the template 30 is pressed against the material to be transferred 60 as in FIG. 2B, some of gaps between the template 30 and the substrate 20 may remain unfilled with the material to be transferred 60. An air gap unfilled with the material to be transferred 60 may remain inside the recessed portion 301, as shown in, for example, FIG. 3B. The states in FIGS. 3A and 3B are both unpreferable because an appropriate pattern is not formed on the material to be transferred 60.

As described above, if the mold releasability for the material to be transferred 60 is enhanced, the problem of reduction in ease of filling with the material to be transferred 60 in compensation for the enhancement may occur. For this reason, the template 30 according to the present embodiment achieves both mold releasability and ease of filling by adding a twist to a configuration of the transfer region PA.

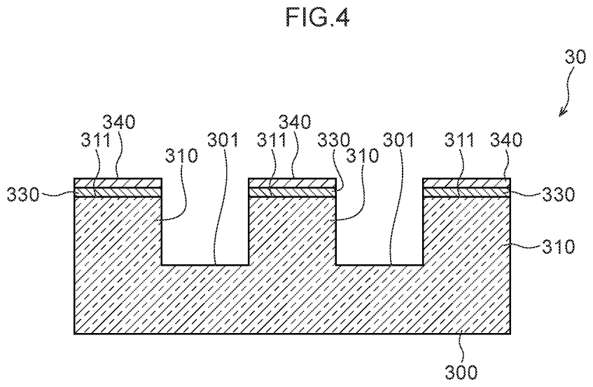

The specific configuration of the template 30 will be described with reference to FIG. 4. The configuration of the transfer region PA of the template 30 is shown as a partial sectional view in FIG. 4. As shown in FIG. 4, the template 30 includes a base material 300, a underlayer film 330, and a monomolecular film 340.

The base material 300 is a member that accounts for almost the whole of the template 30. The base material 300 is made of quartz. A material obtained by causing quartz to contain an additive of some kind may be used as a material for the base material 300 as long as the material is a material transparent to a wavelength of light applied from the light source 40. A material different from quartz may be used. The protruding portions 310 and the recessed portions 301 that constitute the three-dimensional pattern of the transfer region PA are all formed at the base material 300.

The underlayer film 330 is a film that covers a distal end surface 311 of each protruding portion 310. The underlayer film 330 is formed as a metal film having Ti as a main component in the present embodiment. Although a material for the underlayer film 330 may be Ti alone as in the present embodiment, the underlayer film 330 may contain a component other than Ti. The underlayer film 330 is formed as a foundation (or an underlayer) for forming the monomolecular film 340 (to be described next). Note that the underlayer film 330 and the monomolecular film 340 are formed only on the distal end surface 311 of each protruding portion 310 of the transfer region PA of the template 30. In the present embodiment, the underlayer film 330 and the like are not provided in a portion other than the distal end surface 311 in the transfer region PA of the template 30. Note that the underlayer film 330 and the like may be provided in a portion other than the transfer region PA of the template 30.

The monomolecular film 340 is a film that covers the underlayer film 330 from above at the distal end surface 311 of each protruding portion 310. The monomolecular film 340 is a film that is formed as a so-called self-assembled monomolecular film. If a metal film is adopted as the underlayer film 330 as in the present embodiment, a film made of, for example, an organic sulfur molecule like a thiol, such as 1-decanethiol, or a disulfide, such as di-n-hexyl disulfide, is preferably used as the monomolecular film 340. The monomolecular film 340 may contain a material other than an organic sulfur molecule.

Advantages of configuring the template 30 in the above-described manner will be explained. The monomolecular film 340 exposed at the distal end of each protruding portion 310 is lower in wettability with the material to be transferred 60 than a material (quartz in the present embodiment) exposed around the monomolecular film 340. In other words, a contact angle of the material to be transferred 60 with the monomolecular film 340 is larger than a contact angle of the material to be transferred 60 with a portion other than the monomolecular film 340 of the transfer region PA.

As a result, in a state immediately after the material to be transferred 60 is cured, as shown in FIG. 2B, an adhesion strength to the distal end surface 311 of each protruding portion 310 in the material to be transferred 60 is smaller than an adhesion strength to a different portion (e.g., an inner side surface and an inner bottom surface of the recessed portion 301). Note that the term adhesion strength here refers to a force needed to peel two elements from each other.

When the template 30 is removed from the material to be transferred 60 so as to reach the state shown in FIG. 2C, a stress applied to the material to be transferred 60 is highest near a distal end portion of each protruding portion 310, and the material to be transferred 60 starts to be released from the template 30 with the portion as a starting point. A force needed for mold release is largest immediately before the material to be transferred 60 peels off the distal end portions of the protruding portions 310 and is an almost constant small force after the material to be transferred 60 peels off the portions.

For the above-described reason, if the monomolecular film 340 is formed on the distal end surface of each protruding portion 310 as in the present embodiment to reduce a force needed to peel the material to be transferred 60 from the portions, a force needed for mold release can be reduced. This allows prevention of a defect in a film at the time of mold release, as shown in FIG. 3A.

Since an adhesion strength of the material to be transferred 60 is reduced only at the distal end surface of each protruding portion 310, reduction in the ease of filling of the material to be transferred 60 can be minimized. It is thus possible to prevent an air gap from remaining, as shown in FIG. 3B, while preventing a defect in a film at the time of mold release.

Since a thickness of the monomolecular film 340 is about the size of one molecule, even if the monomolecular film 340 is formed at the distal end of each protruding portion 310, a shape of the three-dimensional pattern in the transfer region PA remains virtually unchanged. For this reason, effects on a pattern shape of the material to be transferred 60 after transfer can be reduced to a negligible level.

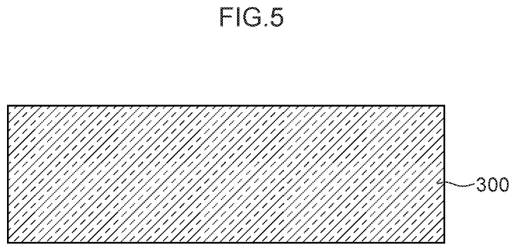

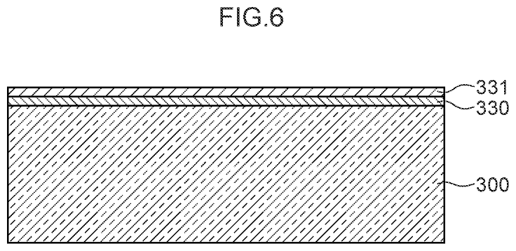

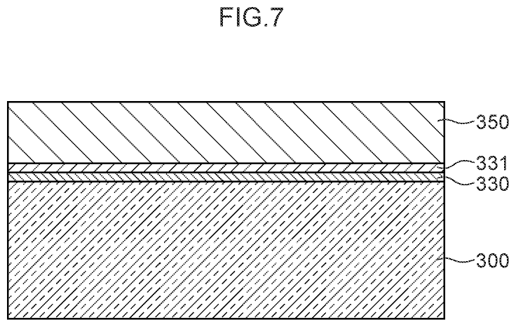

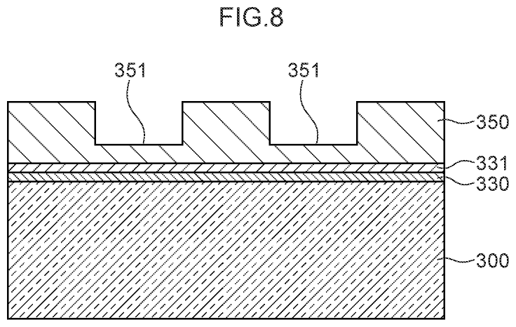

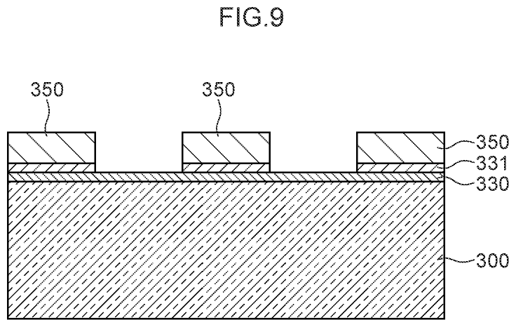

A method for manufacturing the template 30 will be described.

<Base Material Preparation Step> As a base material preparation step, the base material 300 is first prepared. The base material 300 at this time has no pattern, such as the protruding portions 310 and the like, and a whole of the transfer region PA is a flat surface. A section of the prepared base material 300 is schematically drawn in FIG. 5. An upper-side surface of the base material 300 in FIG. 5 is a surface at which the protruding portions 310 and the like are to be formed.

<Underlayer Film Formation Step> Subsequent to the base material preparation step, a underlayer film formation step is performed. In the underlayer film formation step, the underlayer film 330 is formed so as to cover at least a whole of a portion to serve as the transfer region PA of a surface of the base material 300. After that, a metal film 331 is formed so as to cover a whole of the underlayer film 330. As described earlier, Ti is used as the material for the underlayer film 330 in the present embodiment. For example, Cr is used as a material for the metal film 331. These films can both be formed by, for example, sputtering or CVD. A state where the underlayer film formation step is completed is shown in FIG. 6. Note that the embodiment does not need the metal film 331 as long as the underlayer film 330 can be suitably processed.

<Mask Formation Step> Subsequent to the underlayer film formation step, a mask formation step is performed. In the mask formation step, a resist 350 is applied so as to cover a surface of the metal film 331, as shown in FIG. 7. The resist 350 is a film that functions as a mask in a later etching step. A recessed portion 351 is then formed at a part of the resist 350 by imprinting, as shown in FIG. 8. The recessed portion 351 is formed in a portion corresponding to each recessed portion 301. Note that the recessed portions 351 may be formed using not imprinting as in the present embodiment but, for example, electron beam lithography or photolithography. In this case, each recessed portion 351 opens, and the metal film 331 is exposed.

<Etching Step> Subsequent to the mask formation step, the etching step is performed. In the etching step, the resist 350 is subjected to, for example, dry etching. At this time, each recessed portion 351 becomes an opening, and the metal film 331 is etched through the opening after that. A state where the etching of the metal film 331 is completed is shown in FIG. 9. The etching of the metal film 331 can be performed using, for example, a chlorine-based species of gas.

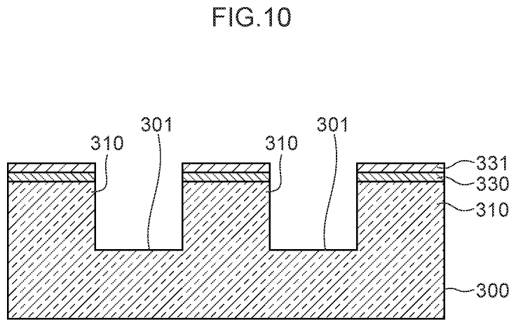

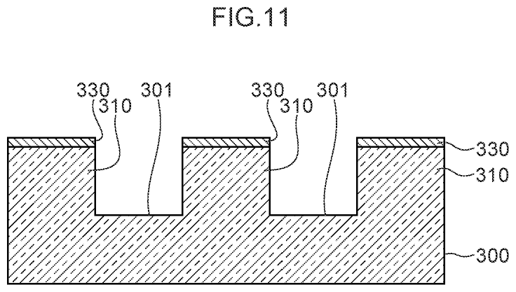

After that, the underlayer film 330 and a part of the base material 300 are also subjected to the etching through the openings in the resist 350. Note that, if the underlayer film 330 is a Ti film as in the present embodiment, each of the underlayer film 330 and the base material 300 can be etched using a CF-based species of gas. Of the transfer region PA of the base material 300, etched portions become the recessed portions 301 described earlier, and the remainder remains as the protruding portions 310. When the etching step is completed, the resist 350 that covers the surface of the metal film 331 is removed, as shown in FIG. 10. The resist 350 can be removed by, for example, using a stripping solution or performing ashing. After that, the metal film 331 is removed by etching to put the underlayer film 330 into an exposed state, as shown in FIG. 11.

<Monomolecular Film Formation Step> Subsequent to the etching step, a monomolecular film formation step is performed. In the monomolecular film formation step, the monomolecular film 340 is formed on a surface of each underlayer film 330. As described earlier, the monomolecular film 340 is formed as a so-called self-assembled monomolecular film. The monomolecular film 340 is selectively formed only on the surface of each underlayer film 330 by, for example, immersing a whole of the base material 300 including the underlayer film 330 in a solution containing an organic sulfur molecule that is an organic material for a predetermined time period. Although the underlayer film 330 may be formed by this solution method, the underlayer film 330 may be formed by a gas phase method. By the above-described method, the template 30 with the configuration shown in FIG. 4 is completed.

As materials for the underlayer film 330 and the monomolecular film 340, materials different from those in the present embodiment may be used. The underlayer film 330 is provided for the purpose of ensuring adhesion to quartz as the base material 300 and forming a self-assembled monomolecular film on the underlayer film 330. The material for the underlayer film 330 is preferably appropriately selected in view of adhesion to the base material 300, the material for the monomolecular film 340 to be formed, and transparency to light emitted from the light source 40.

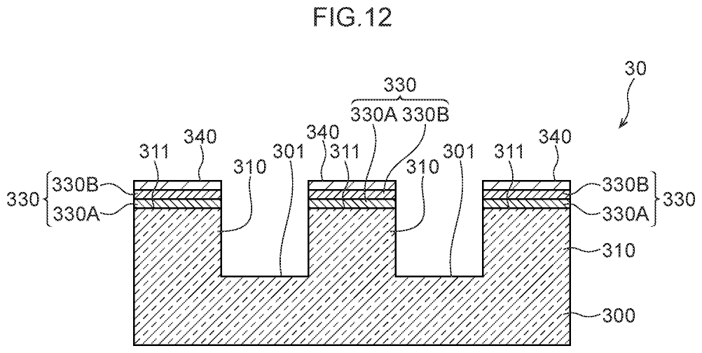

Although the underlayer film 330 may be a one-layered metal film as in the present embodiment, the underlayer film 330 may be a two-layered metal film as in a modification shown in FIG. 12. In the example in FIG. 12, a first underlayer film 330A covers the distal end surface 311, and a second underlayer film 330B covers the first underlayer film 330A. The first underlayer film 330A is a film having, for example, Cr, Ti or Fe—Ni—Cr alloy as a main component, and the second underlayer film 330B is a film having, for example, Au, Ti, Ag, Cu, Fe, Ni, Zn, Pt, or Pd as a main component. A material for the first underlayer film 330A may be Cr alone as in the modification or may contain a component other than Cr. Similarly, a material for the second underlayer film 330B may be Au, Ti, Ag, Cu, Fe, Ni, Zn, Pt, or Pd alone as in the modification or may contain a component other than Au, Ti, Ag, Cu, Fe, Ni, Zn, Pt, or Pd.

As described above, if an organic sulfur molecule is used as a material for the monomolecular film 340, the underlayer film 330 only needs to be a film containing at least one of Ti, Au, Ag, Cu, Fe, Ni, Zn, Pt, and Pd. The number of layers of the underlayer film 330 may be two as in the modification or may be three or more.

Note that, if the underlayer film 330 is a film containing at least one of Ti, Au, Ag, Cu, Fe, Ni, Zn, Pt, and Pd, the underlayer film 330 may be removed by etching, such as dry etching or wet etching. Among these, if the underlayer film 330 is a film containing Ti, for example, the underlayer film 330 may be removed by dry etching using a CF-based species of gas as in the present embodiment in an etching step. If the underlayer film 330 has a layer made of Cr and Au, the layer may be removed by dry etching using a chlorine-based species of gas in the etching step.

The monomolecular film 340 containing an organic sulfur molecule, such as alkylthiol, dialkyldisulfide, thiocyanate, thioacetate, alkylselenolate, alkyltellurolate, dialkyldiselenide, isocyanide, isocyanate, or alkylsilane, may further contain fluorine. Among these, alkylthiol, dialkyldisulfide, thiocyanate, or thioacetate may be preferably used as these materials are relatively easy to be deposited and also readily available. Specifically, the monomolecular film 340 may be formed from, for example, a fluorinated organic sulfur molecule, such as 1H, 1H, 2H, 2H-perfluorodecanethiol. Use of such a material allows further increase in a contact angle of the material to be transferred 60 with the monomolecular film 340.

The underlayer film 330 may be formed from not a metal as in the present embodiment but a metal oxide. For example, a metal oxide containing at least one of Al₂O₃, TiOz, ZrO₂, Ag₂O, CuO, Ta₂O₅, and ITO that is a mixed oxide of In₂O₃ and SnO₂ can be used as the metal oxide. The underlayer film 330 may be a metal oxide itself as described above or may contain a component other than the metal oxide.

If a metal oxide as described above is adopted for the underlayer film 330, it is preferable to use a film made of phosphonic acid, alkylphosphonate, carboxylic acid, or alkylamine as the monomolecular film 340. The monomolecular film 340 may contain a material other than phosphonic acid, alkylphosphonate, carboxylic acid, or alkylamine.

The monomolecular film 340 containing phosphonic acid, alkylphosphonate, carboxylic acid, or alkylamine may further contain fluorine. Among these, phosphonic acid may be preferably used because its adhesion is relatively high. Specifically, the monomolecular film 340 may be formed from, for example, an alkyl phosphonic acid, such as n-octadecylphosphonic acid, or a fluorinated phosphonic acid, such as 1H, 1H, 2H, 2H-perfluorooctanephosphonic acid. Use of such a material allows further increase in the contact angle of the material to be transferred 60 with the monomolecular film 340.

The underlayer film 330 may be formed from, for example, a compound semiconductor, such as GaAs, InP, or GaN. When the underlayer film 330 is formed from the compound semiconductor, the monomolecular film 340 may be formed from, for example, a material containing alkylthiol.

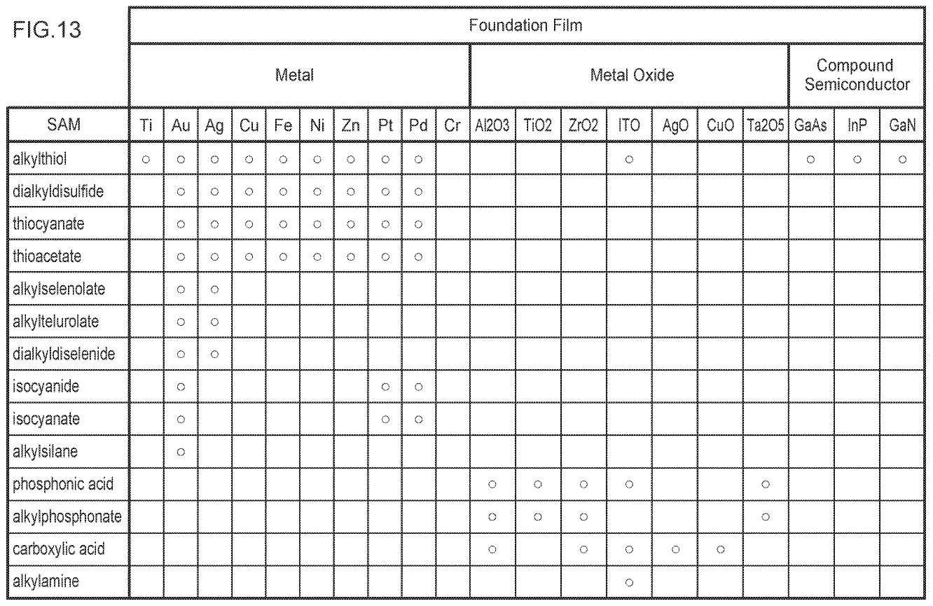

FIG. 13 is a table showing the relationship between the materials that can be used to form the monomolecular film 340 (self-assembled monolayer (SAM)) and the materials that can be used to form the underlayer film 330, as described above. In FIG. 13, metals, metal oxides, and compound semiconductors of the underlayer film 330 are indicated by a circle, if they can be suitably used for each material of the monomolecular film 340, listed in the column of SAM.

Even if any of the above-described materials is used for the underlayer film 330, a thickness of the underlayer film 330 is preferably thinned as much as possible so as to fall inside a range of up to 10 nm.

If pattern transfer using the template 30 is repeatedly performed, the monomolecular film 340 at a distal end of the protruding portion 310 wears gradually. However, since the monomolecular film 340 as a self-assembled monomolecular film can be relatively quickly and easily formed, the monomolecular film 340 may be appropriately touched up in accordance with the degree of wear.

If a material containing the material for the monomolecular film 340 is used for the material to be transferred 60 at the time of pattern transfer using the imprinting apparatus 10, the monomolecular film 340 is repaired upon contact with the material to be transferred 60 each time a pattern is transferred as in FIG. 2B. Mold releasability of the template 30 can be maintained over a long period without frequently touching up the monomolecular film 340.

The present embodiment has been described above with reference to the specific examples. The present disclosure, however, is not limited to the specific examples. Examples obtained by making appropriate design changes to the specific examples by those skilled in the art are also included in the scope of the present disclosure as long as the examples have features of the present disclosure. Elements included in each of the specific examples described earlier and arrangements, conditions, shapes, and the like thereof are not limited to those illustrated above and can be appropriately changed. The combination of the elements included in each specific example can be appropriately changed unless there is a technical contradiction.

What is claimed is:

1. A template for imprinting that transfers a pattern onto a material to be transferred on a substrate, comprising:
a base material in which a protruding portion corresponding to the pattern is formed in a transfer region to be pressed against the material to be transferred;
a underlayer film that covers, of the transfer region, only a distal end surface of the protruding portion; and
a monomolecular film that covers the underlayer film.

2. The template according to claim 1, wherein
a contact angle of the material to be transferred with respect to the monomolecular film is larger than a contact angle of the material to be transferred with respect to a portion other than the monomolecular film of the transfer region.

3. The template according to claim 1, wherein
the base material contains quartz.

4. The template according to claim 1, wherein
the underlayer film contains a metal.

5. The template according to claim 4, wherein
the underlayer film contains at least one of titanium, chromium, gold, silver, copper, iron, nickel, zinc, platinum, and palladium.

6. The template according to claim 5, wherein
the monomolecular film contains an organic sulfur molecule of at least one of alkylthiol, dialkyldisulfide, thiocyanate, thioacetate, alkylselenolate, alkyltellurolate, dialkyldiselenide, isocyanide, isocyanate, and alkylsilane.

7. The template according to claim 5, wherein
the monomolecular film contains at least one of alkylthiol, dialkyldisulfide, thiocyanate, and thioacetate.

8. The template according to claim 6, wherein
the monomolecular film contains fluorine.

9. The template according to claim 7, wherein
the monomolecular film contains fluorine.

10. The template according to claim 1, wherein
the underlayer film contains a metal oxide.

11. The template according to claim 10, wherein
the underlayer film contains an oxide of at least one of aluminum, titanium, zirconium, silver, copper, tantalum, tin, and indium.

12. The template according to claim 11, wherein
the monomolecular film contains at least one of a phosphonic acid, an alkylphosphonate, a carboxylic acid, and an alkylamine.

13. The template according to claim 11, wherein
the monomolecular film contains a phosphonic acid.

14. The template according to claim 12, wherein
the monomolecular film contains fluorine.

15. The template according to claim 13, wherein
the monomolecular film contains fluorine.

16. The template according to claim 1, wherein
a thickness of the underlayer film is not more than 10 nm.

17. A manufacturing method for a template for imprinting, comprising:
forming a underlayer film on a surface of a base material;
covering the underlayer film with a mask;
etching the underlayer film and the base material through an opening in the mask; and
forming a monomolecular film on a surface of the remaining underlayer film.

18. The manufacturing method for the template according to claim 17, wherein
the monomolecular film is a self-assembled monomolecular film.

19. A manufacturing method for a substrate with a pattern using a template, comprising:
a step of arranging a material to be transferred on a surface of the substrate;
a step of pressing the template against the material to be transferred;
a step of applying light to cure the material to be transferred; and
a step of removing the template from the material to be transferred,
wherein the manufacturing method uses, as the template,
a template including
a base material in which a protruding portion corresponding to the pattern is formed in a transfer region to be pressed against the material to be transferred,
a underlayer film that covers, of the transfer region, only a distal end surface of the protruding portion, and
a monomolecular film that covers the underlayer film.

20. The manufacturing method for the substrate with the pattern according to claim 19, wherein
the manufacturing method uses, as the material to be transferred, a material containing a material for the monomolecular film.
